(19) United States
(12) Patent Application Publication
(10) Pub. No.: US 2026/0147270 A1
(43) Pub. Date: May 28, 2026

(54) LINE CD MODULATION AND END-TO-END CD MANIPULATION WITH ANGLED ETCH & DEPOSITION

(71) Applicant: Applied Materials, Inc., Santa Clara, CA (US)

(72) Inventors: Chen-Chih Hsu, Gloucester, MA (US); Yung-Chen Lin, Westwood, MA (US); Shurong Liang, Lynnfield, MA (US); Steven Sherman, Newton, MA (US)

(73) Assignee: Applied Materials, Inc., Santa Clara, CA (US)

(21) Appl. No.: 19/183,305

(22) Filed: Apr. 18, 2025

Related U.S. Application Data
(60) Provisional application No. 63/726,195, filed on Nov. 27, 2024.

(51) Int. Cl. G03F 1/80; H01L 21/033

(52) U.S. Cl. CPC G03F 1/80; H10P 76/405; H10P 76/4085

(57) ABSTRACT

Disclosed herein are approaches for line critical dimension (CD) modulation and end-to-end CD reduction with angled etch and angled deposition. One method may include forming a plurality of patterning lines over a stack of layers, wherein each of the patterning lines includes first and second sidewalls. The method may further include delivering one or more reactive plasma beams to the patterning lines at a non-zero angle relative to a perpendicular to a plane defined by an upper surface of the patterning lines, wherein the one or more reactive plasma beams modulate a line CD between a first pair of adjacent patterning lines by performing at least one of the following: an angled etch to remove a material of the patterning lines from the first and second sidewalls, and an angled deposition to form an additional material along the first and second sidewalls.

### CROSS-REFERENCE TO RELATED APPLICATIONS

The present application claims priority to U.S. Provisional Ser. No. 63/726,195, filed Nov. 27, 2024, and entitled “LINE CD MODULATION AND END-TO-END CD MANIPULATION WITH ANGLED ETCH AND DEPOSITION”, and incorporates its disclosure herein by reference in its entirety.

### FIELD OF THE DISCLOSURE

The present disclosure relates to semiconductor device patterning and, more particularly, to line critical dimension (CD) modulation and end-to-end CD manipulation with angled etch and angled deposition.

### BACKGROUND OF THE DISCLOSURE

Blocking and patterning features are widely used for creating 2D and 3D patterns in microelectronic devices. Lithography is one such approach, and involves deposition of an underlayer and a film (e.g., photoresist) over the underlayer. However, as process geometries continue to decrease, CD of features of the underlayer(s) and/or film are becoming continually smaller, making processing more challenging.

It is with respect to these and other considerations that the present disclosure is provided.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

One method includes forming a plurality of patterning lines over a stack of layers, wherein each of the plurality of patterning lines comprises a first sidewall and a second sidewall, and delivering one or more reactive plasma beams to the plurality of patterning lines at a non-zero angle relative to a perpendicular to a plane defined by an upper surface of the plurality of patterning lines. The one or more reactive plasma beams modulate a line critical dimension (CD) between a first pair of adjacent patterning lines of the plurality of patterning lines by performing at least one of the following: an angled etch to remove a material of the plurality of patterning lines from the first sidewall and the second sidewall, and an angled deposition to form an additional material along the first sidewall and the second sidewall.

A processing apparatus may include a chamber operable to contain a plasma within a chamber volume, the chamber defined by a plurality of sidewalls, and a plate assembly proximate the chamber, wherein ions are extracted through a plurality of apertures of the plate assembly and delivered to a semiconductor device as a reactive plasma beam oriented at a non-zero angle relative to a perpendicular extending from an upper surface of a stack of layers of the semiconductor device. Therein the reactive plasma beam modulates a line critical dimension (CD) between a first pair of adjacent patterning lines of the plurality of patterning lines by performing an angled etch to remove a material of the plurality of patterning lines from at least one of the following: the first sidewall, the second sidewall, and an upper surface extending between the first and second sidewalls. The reactive plasma beam further additionally or alternatively modulates the line CD between the first pair of adjacent patterning lines of the plurality of patterning lines by performing an angled deposition to form an additional material along at least one of the following: the first sidewall, the second sidewall, and the upper surface extending between the first and second sidewalls.

A method of modifying a plurality of resist lines formed over a stack of layers, may include delivering one or more reactive plasma beams to the plurality of resist lines at a non-zero angle relative to a perpendicular to a plane defined by an upper surface of the stack of layers. The reactive plasma beam modulates a line critical dimension (CD) between a first pair of adjacent resist lines of the plurality of resist lines by performing at least one of the following: an angled etch to remove a material of the plurality of resist lines from at least one of the following: the first sidewall, the second sidewall, and an upper surface extending between the first and second sidewalls, and an angled deposition to form an additional material along at least one of the following: the first sidewall, the second sidewall, and the upper surface extending between the first and second sidewalls.

### BRIEF DESCRIPTION OF THE DRAWINGS

The accompanying drawings illustrate exemplary approaches of the disclosure, including the practical application of the principles thereof, as follows:

FIG. 1A is a side cross-sectional view of a device including a plurality of patterning features formed atop an upper surface of a stack of layers, according to embodiments of the present disclosure;

FIG. 1B is a top view of the device of FIG. 1A, according to embodiments of the present disclosure; and

FIG. 2A is a top view of the device during a reactive plasma beam treatment, according to embodiments of the present disclosure;

FIG. 2B is a side cross-sectional view of the device of FIG. 2A during the reactive plasma beam treatment, according to embodiments of the present disclosure;

FIG. 3A is a top view of the device following a reactive plasma beam treatment, according to embodiments of the present disclosure;

FIG. 3B is a side cross-sectional view of the device of FIG. 3A following the reactive plasma beam treatment, according to embodiments of the present disclosure;

FIG. 4A is a top view of the device following a reactive plasma beam treatment, according to embodiments of the present disclosure;

FIG. 4B is a side cross-sectional view of the device of FIG. 4A following the reactive plasma beam treatment, according to embodiments of the present disclosure;

FIG. 5A is a top view of a device including a plurality of patterning features formed atop an upper surface of a stack of layers, according to embodiments of the present disclosure;

FIG. 5B is a side cross-sectional view of the device of FIG. 5A, according to embodiments of the present disclosure;

FIG. 6A is a top view of the device following a reactive plasma beam treatment, according to embodiments of the present disclosure;

FIG. 6B is a side cross-sectional view of the device of FIG. 6A following the reactive plasma beam treatment, according to embodiments of the present disclosure;

FIG. 7A is a top view of a device including a plurality of patterning features formed atop an upper surface of a stack of layers, according to embodiments of the present disclosure;

FIG. 7B is a side cross-sectional view of the device of FIG. 7A, according to embodiments of the present disclosure;

FIG. 8A is a top view of the device following a reactive plasma beam treatment, according to embodiments of the present disclosure;

FIG. 8B is a side cross-sectional view of the device of FIG. 8A following the reactive plasma beam treatment, according to embodiments of the present disclosure;

FIG. 9A is a top view of a device including a plurality of patterning features formed atop an upper surface of a stack of layers, according to embodiments of the present disclosure;

FIG. 9B is a side cross-sectional view of the device of FIG. 9A, according to embodiments of the present disclosure;

FIG. 10A is a top view of the device during a reactive plasma beam treatment, according to embodiments of the present disclosure;

FIG. 10B is a side cross-sectional view of the device of FIG. 10A during the reactive plasma beam treatment, according to embodiments of the present disclosure;

FIG. 11 is a top view of the device following a reactive plasma beam treatment, according to embodiments of the present disclosure;

FIG. 12A is a top view of a device including a plurality of patterning features formed atop an upper surface of a stack of layers, according to embodiments of the present disclosure;

FIG. 12B is a side cross-sectional view of the device of FIG. 12A, according to embodiments of the present disclosure;

FIG. 13A is a top view of the device following a reactive plasma beam treatment, according to embodiments of the present disclosure;

FIG. 13B is a side cross-sectional view of the device of FIG. 13A following the reactive plasma beam treatment, according to embodiments of the present disclosure;

FIG. 14 shows a semiconductor processing apparatus according to embodiments of the disclosure;

FIG. 15A depicts a system according to embodiments of the disclosure; and

FIG. 15B depicts a plan view of an apparatus of the system of FIG. 15A according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, device, and systems in accordance with the present disclosure will now be described more fully hereinafter with reference to the accompanying drawings, where various embodiments are shown. The methods and systems may be embodied in many different forms and are not to be construed as being limited to the embodiments set forth herein. Instead, these embodiments are provided so the disclosure will be thorough and complete, and will fully convey the scope of the methods to those skilled in the art.

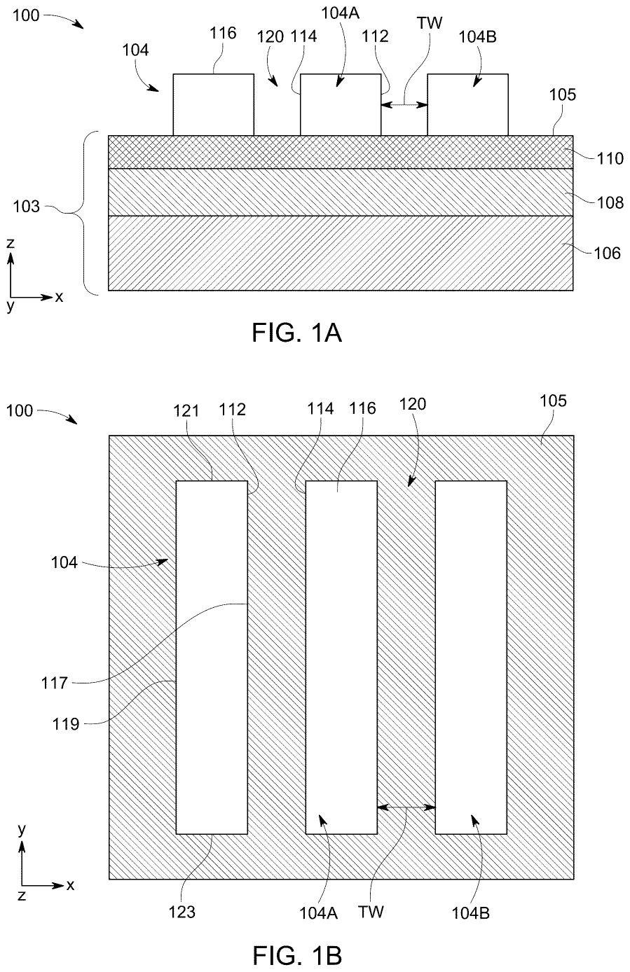

FIG. 1A depicts a portion of a semiconductor device (hereinafter “device”) 100, according to one or more embodiments. The device 100 may include a stack of layers 103, and a plurality of patterning features or lines 104 formed atop an upper surface 105 of the stack of layers 103. Although non-limiting, the stack of layers 103 may include a base layer 106, a first underlayer 108 formed over the base layer 106, and a second underlayer 110 formed over the first underlayer 108. In some embodiments, the first and second underlayers 108, 110 are hardmask layers. In some embodiments, the second underlayer 110 may be a silicon-containing hardmask (e.g., aSi, SiC, SiB, SiO2, SiN, SiON etc.). The stack of layers 103 may include additional layers not shown.

In some embodiments, the plurality of patterning lines 104 are formed from a photoresist layer into a desired pattern and shape. For example, each of the plurality of patterning lines 104 may include a first side 117 opposite a second side 119, and a first end 121 opposite a second end 123. The first side 117 may be defined by a first sidewall 112, and the second side 119 may be defined by a second sidewall 114. A top surface 116 extends between the first and second sidewalls 112, 114. The plurality of patterning lines 104 may be defined by a plurality of openings or trenches 120 formed selective to the upper surface 105 of the stack of layers 103. The trenches 120 may have a line critical dimension (CD) (hereinafter trench width (TW)) extending in the x-direction, between the first sidewall 112 and the second sidewall 114 of a first pair of adjacent patterning lines 104A, 104B. In the embodiment shown, the trench width is substantially the same for each of the trenches 120 of the device 100.

In the embodiment shown, the plurality of patterning lines 104 are formed from an extreme ultraviolet (EUV) or deep ultraviolet (DUV) resist, such as metal-oxide resist (MOR) or a chemically amplified resist (CAR).

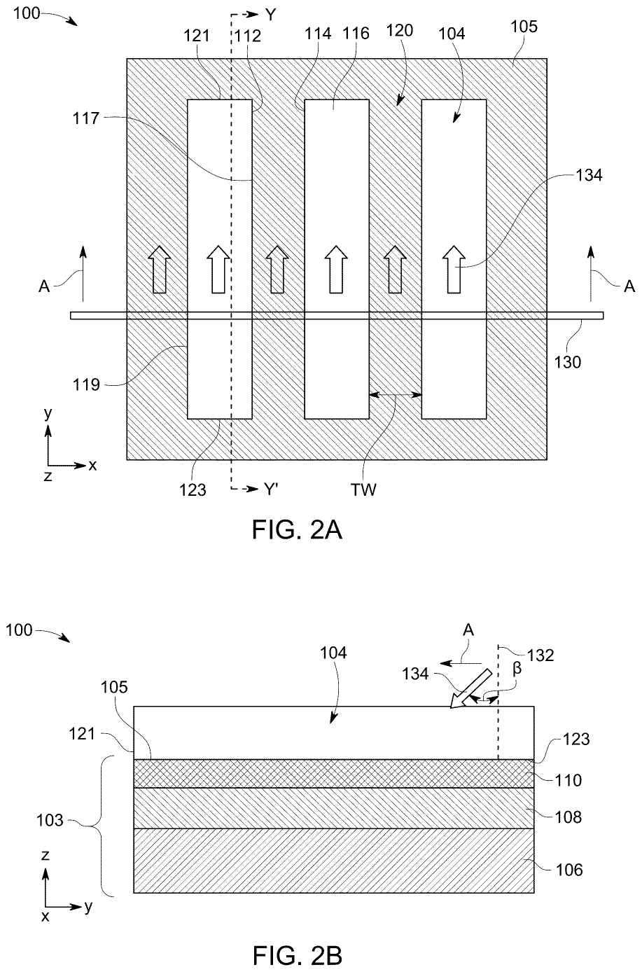

Following formation of the plurality of patterning lines 104, it may be desirable to adjust one or more dimensions of the plurality of patterning lines 104 and/or the trenches 120. To accomplish this, as shown in FIGS. 2A-2B , a reactive plasma beam 130 may be delivered to the plurality of patterning lines 104 at a non-zero angle (β) relative to a perpendicular 132 (FIG. 2B) to a plane defined by the upper surface 105 of the stack of layers 103. That is, angled plasma ions 134 from the reactive plasma beam 130 may either etch the patterning lines 104 or form additional material along the patterning lines 104 as the reactive plasma beam 130 is moving/scanning across the device 100, e.g., in the y-direction, as shown by arrow ‘A’. The angled plasma ions 134 may be delivered parallel and/or perpendicular to a plane defined by the first and second sidewalls 112, 114. Although non-limiting, the angled plasma ions 134 may include a gas species suitable for dilution, such as helium (He), argon (Ar), nitrogen (N2), etc. Other etch or deposition chemistries may be used in alternative embodiments. For example, in other embodiments, one of the following angled ion etch chemistries may be used: Ar+, N+, He+, H+, O+, CH+, CF+, CxHyF+, CO+, COS+, BCl3+, although the present disclosure is not limited in this regard.

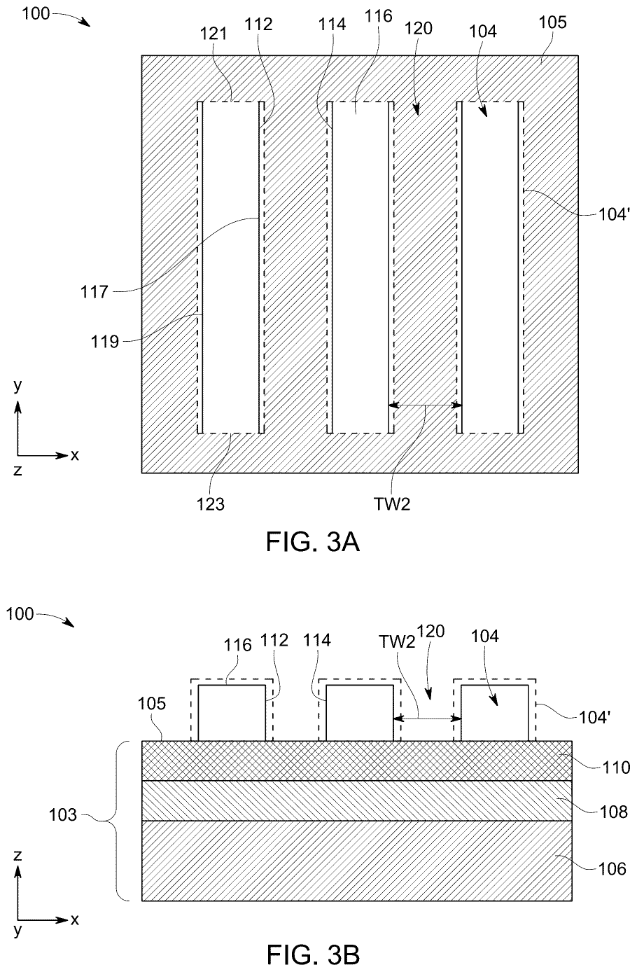

When etching is desired, the reactive plasma beam 130 may remove (e.g., etch) material from each of the patterning lines 104, as demonstrated in FIGS. 3A-3B . That is, a portion of the first and second sidewalls 112, 114 and the top surface 116 of the patterning lines 104 may be reduced from the original patterning lines, which are demonstrated by dashed lines 104′. A width of each trench 120, ‘TW2’, is increased as a result of the removal process, while a height (e.g., in the z-direction) is reduced. In some embodiments, the reactive plasma beam 130 does not significantly impact the upper surface 105 of the stack of layers 103.

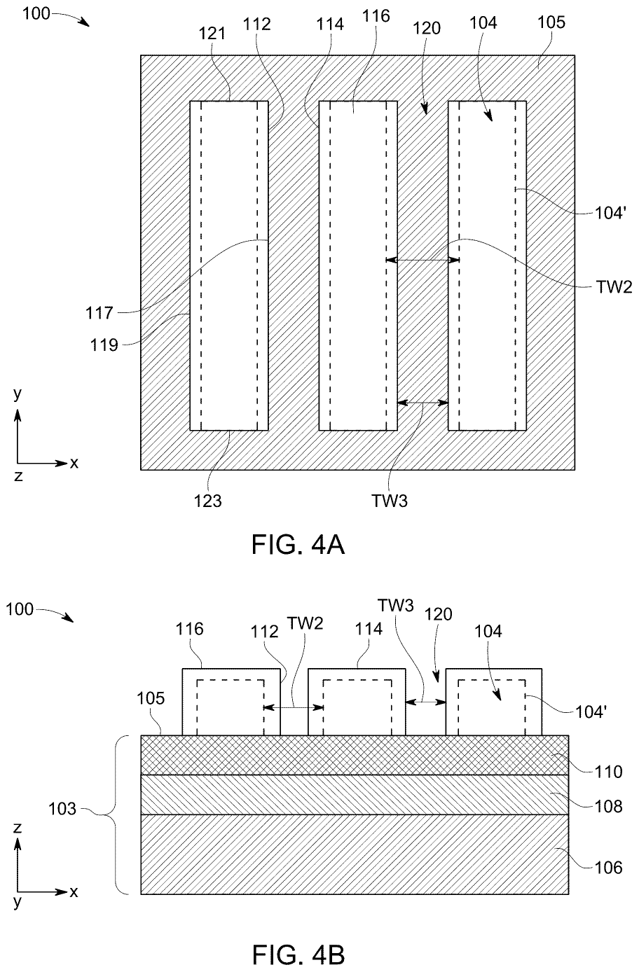

In the embodiment of FIGS. 4A-4B, the reactive plasma beam 130 (FIGS. 2A-2B) may be used to form or deposit additional material along the patterning lines 104. That is, the angled plasma ions 134 are delivered to the plurality of patterning lines 104 at the non-zero angle (β) to conformally form material (e.g., one or more film layers) along the first and second sidewalls 112, 114, and along the top surface 116 of the patterning lines 104. In some embodiments, the material may be a carbon-based film or a silicon-based film with various precursors. For example, the film layer may be carbon with an CO, COS or CH4 precursor, aSi, SiOx with a SiCl4 or O2 precursor, SiN with a SiCl4 or N2 precursor, or boron with a BCl3 precursor. In other embodiments, a fluorine-based chemistry may be used.

As a result, the patterning lines 104 may be enlarged from the original patterning lines, which are demonstrated by dashed lines 104′. A width ‘TW3’ of each trench 120 following the deposition process, is therefore reduced from an original width ‘TW2’. A height (e.g., in the y-direction) may also be reduced. Advantageously, the additional material may be formed along the patterning lines 104 without being significantly formed along the upper surface 105 of the stack of layers 103.

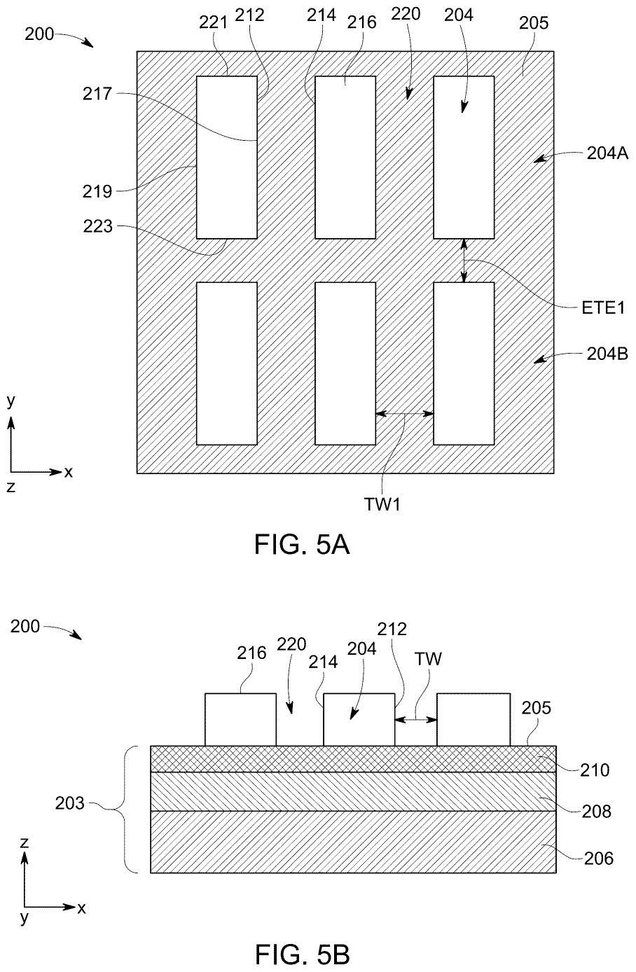

FIGS. 5A-5B depict a portion of another semiconductor device (hereinafter “device”) 200, according to one or more embodiments. The device 200 may include a stack of layers 203, and a plurality of patterning features or lines 204 formed atop an upper surface 205 of the stack of layers 203. Although non-limiting, the stack of layers 203 may include a base layer 206, a first underlayer 208 formed over the base layer 206, and a second underlayer 210 formed over the first underlayer 208.

In some embodiments, the plurality of patterning lines 204 are formed from a photoresist layer into a desired pattern and shape. Each of the plurality of patterning lines 204 may include a first sidewall 212 opposite a second sidewall 214, and an top surface 216 extending between the first and second sidewalls 212, 214. Furthermore, each of the patterning lines 204 may include a first side 217 opposite a second side 219, and a first end 221 opposite a second end 223. The plurality of patterning lines 204 may be defined by a plurality of openings or trenches 220 formed selective to the upper surface 205 of the stack of layers 203. The trenches 220 may have a trench width (TW1) extending in the x-direction, between the first sidewall 212 and the second sidewall 214 of adjacent patterning lines 204. In the embodiment shown, the trench width is substantially the same for each of the trenches 220 of the device 200.

In the embodiment shown, the plurality of patterning lines 204 may be arranged in rows, such as a first row 204A and a second row 204B, wherein the first and second rows 204A, 204B are separated from one another by an end-to-end distance (ETE1). More specifically, ETE1 represents an end-to-end CD between the first end 221 of the second row 204B of patterning lines 204 and the second end 223 of the first row 204A of the patterning lines 204.

Following formation of the plurality of patterning lines 204, one or more reactive plasma beams may be delivered to the plurality of patterning lines 204 at a non-zero angle (as described above with respect to FIGS. 2A-2B) . That is, angled plasma ions from the reactive plasma beam may either etch the patterning lines 204 or form or deposit additional material along the patterning lines 204 as the reactive plasma beam is moving/scanning across the device 200, e.g., in the y-direction. The angled plasma ions may also be delivered parallel and/or perpendicular to a plane defined by the first and second sidewalls 212, 214. The etch and deposition processes may occur sequentially, but they may also occur simultaneously, by running both the etch and the deposition chemistries at the same time.

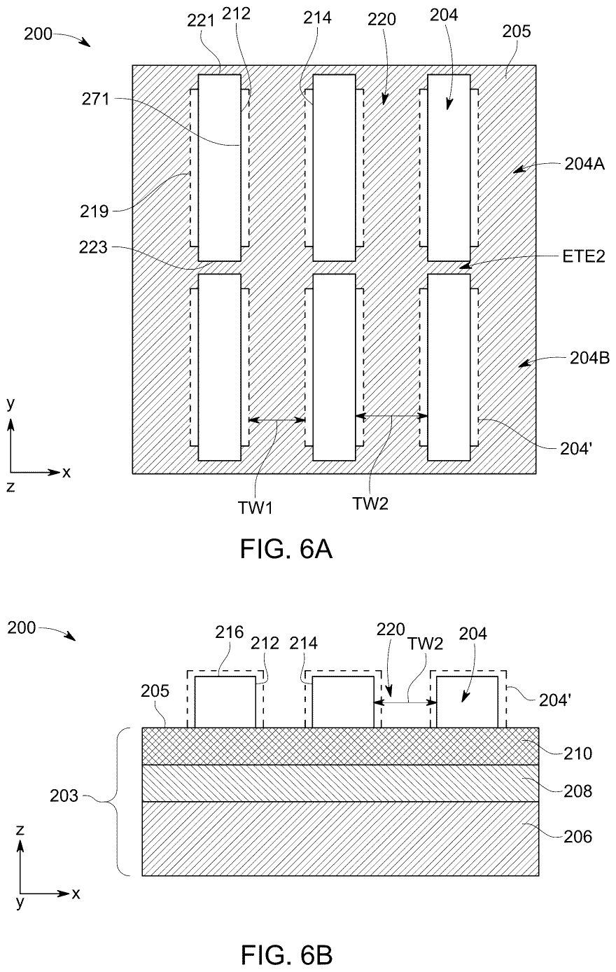

In the embodiment shown in FIGS. 6A-6B , an etch process is performed to remove material from each of the patterning lines 204. That is, a portion of the first and second sidewalls 212, 214 and the top surface 216 of the patterning lines 204 may be removed to reduce the original patterning lines in the x-direction, which are demonstrated by dashed lines 204′. As a result, a width of each trench 220, ‘TW2’, is increased following the removal process.

Another reactive plasma beam may then be used to form additional material along the patterning lines 204. That is, the angled plasma ions are delivered to the plurality of patterning lines 204 at a non-zero angle to conformally form material at the first and second ends 221, 223 of each of the patterning lines 204. The additional material may also be formed along the top surface 216 of the patterning lines 204. The non-zero angle of the plasma deposition process may be the same or different as the non-zero angle of the plasma etch process. As a result, the patterning lines 204 may be enlarged, e.g., in the y-direction, from the original patterning lines, which are demonstrated by dashed lines 204′. In turn, the end-to-end distance between the first and second rows 204A, 204B may be reduced (shown as ETE2). Again, the processes to both remove and add material the patterning lines 204 may occur sequentially, but they may also occur simultaneously, by running both the etch and the deposition chemistries at the same time.

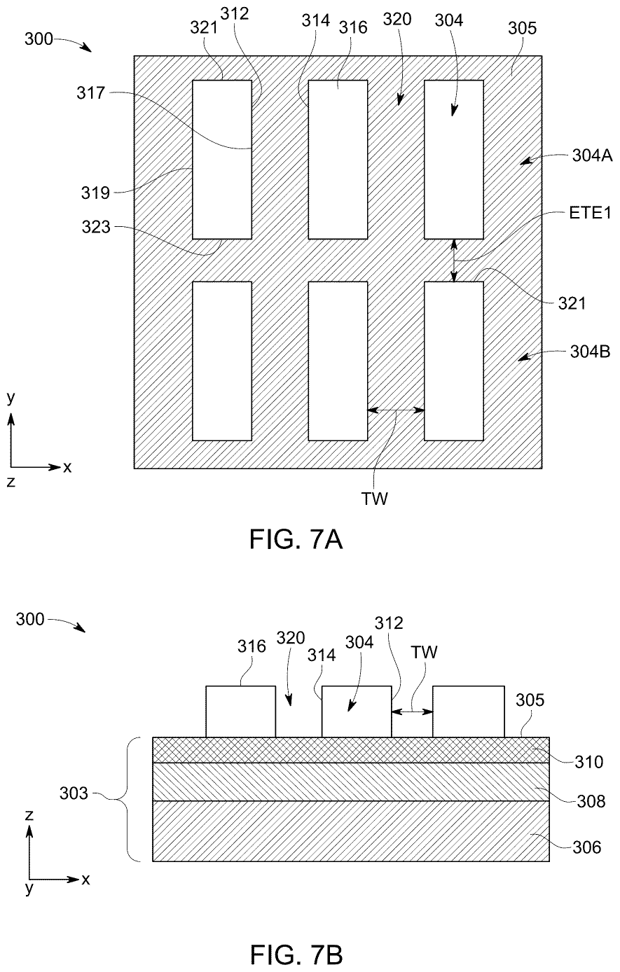

FIGS. 7A-7B depict a portion of another semiconductor device (hereinafter “device”) 300, according to one or more embodiments. The device 300 may include a stack of layers 303, and a plurality of patterning features or lines 304 formed atop an upper surface 305 of the stack of layers 303. Although non-limiting, the stack of layers 303 may include a base layer 306, a first underlayer 308 formed over the base layer 306, and a second underlayer 310 formed over the first underlayer 308.

In some embodiments, the plurality of patterning lines 304 are formed from a photoresist layer into a desired pattern and shape. Each of the plurality of patterning lines 304 may include a first sidewall 312 opposite a second sidewall 314, and an top surface 316 extending between the first and second sidewalls 312, 314. Furthermore, each of the patterning lines 304 may include a first side 317 opposite a second side 319, and a first end 321 opposite a second end 323. The plurality of patterning lines 304 may be defined by a plurality of openings or trenches 320 formed selective to the upper surface 305 of the stack of layers 303. The trenches 320 may have a trench width (TW) extending in the x-direction, between the first sidewall 312 and the second sidewall 314 of adjacent patterning lines 304.

In the embodiment shown, the plurality of patterning lines 304 may be arranged in rows, such as a first row 304A and a second row 304B, wherein the first and second rows 304A, 304B are separated from one another by an end-to-end distance (ETE1). More specifically, ETE1 represents a dimension between the first end 321 of the second row 304B of patterning lines 304 and the second end 323 of the first row 304A of the patterning lines 304.

Following formation of the plurality of patterning lines 304, one or more reactive plasma beams may be delivered to the plurality of patterning lines 304 at a non-zero angle (as described above with respect to FIGS. 2A-2B) . That is, angled plasma ions from the reactive plasma beam may either etch the patterning lines 304 and/or form additional material along the patterning lines 304 as the reactive plasma beam is moving/scanning in the y-direction. The angled plasma ions may also be delivered parallel and/or perpendicular to a plane defined by the first and second sidewalls 312, 314.

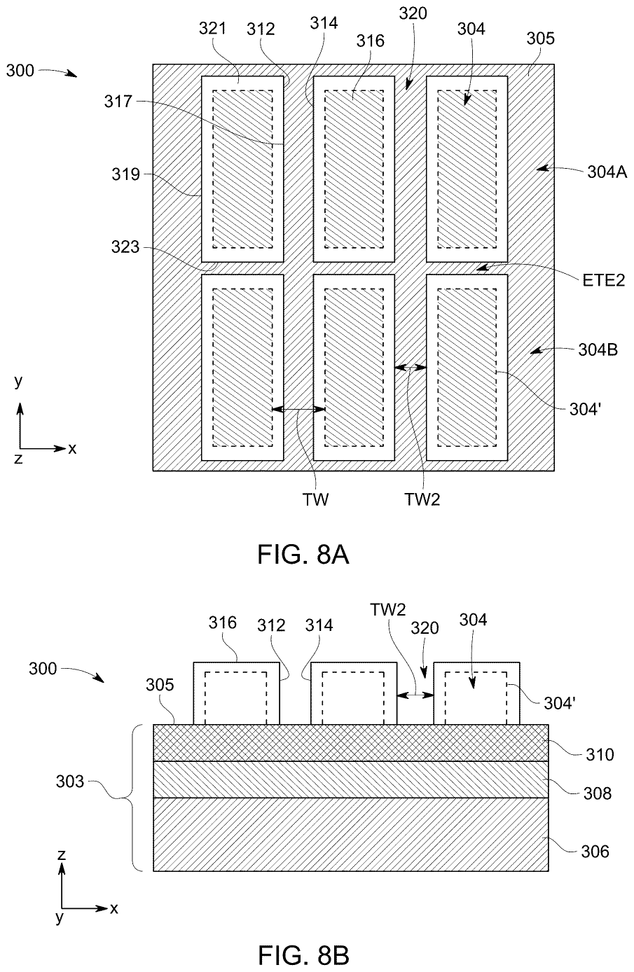

In the embodiment shown in FIGS. 8A-8B , a plasma deposition process is performed to add material to each of the patterning lines 304. That is, material is added to each of the first and second sidewalls 312, 314 and to the top surface 316 of the patterning lines 304. The material may also be conformally formed on the first and second ends 321, 323 of each of the patterning lines 304. As a result, the patterning lines are enlarged in the x-direction, the y-direction, and z-direction. Dashed lines 304′ demonstrate the original patterning lines prior to the plasma treatment. As a result, a width of each trench 320, ‘TW2’, is decreased following the material formation process, and the end-to-end distance between the first and second rows 304A, 304B may be reduced (shown as ETE2).

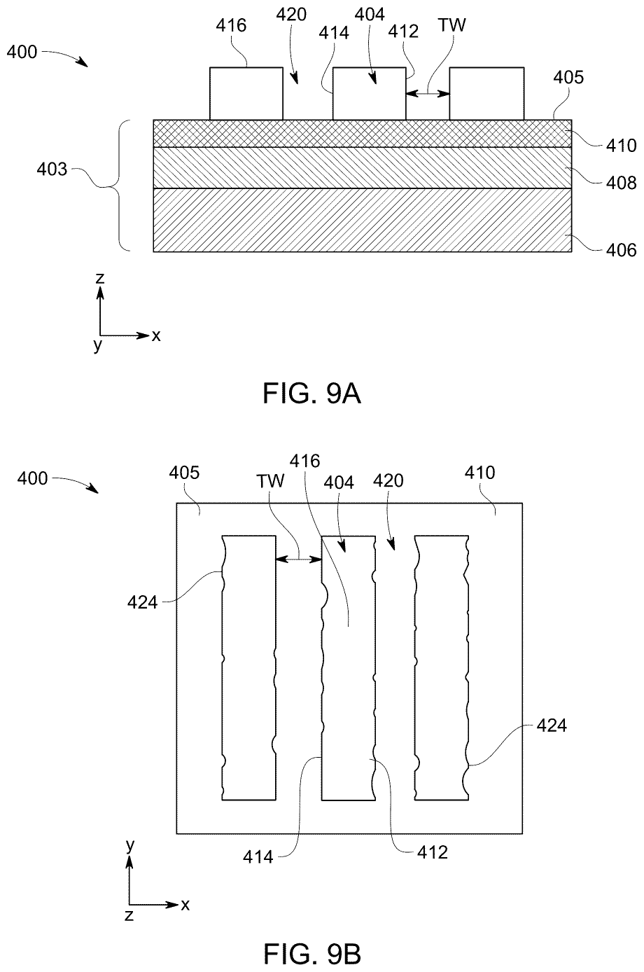

FIGS. 9A-11 demonstrate an approach for addressing surface roughness along the plurality of patterning lines 404 of a device 400. As better shown in the top view of FIG. 9B, one or more areas of surface roughness 424 may be present along at least one of the first sidewall 412 and the second sidewall 414 of the patterning lines 404. The areas of surface roughness 424 may include relatively larger protrusions and/or indentations along the surfaces of the patterning lines 404 after formation of the patterning lines 404. The areas of surface roughness 424 can take on any variety of shapes and sizes. Embodiments herein are not limited in this context.

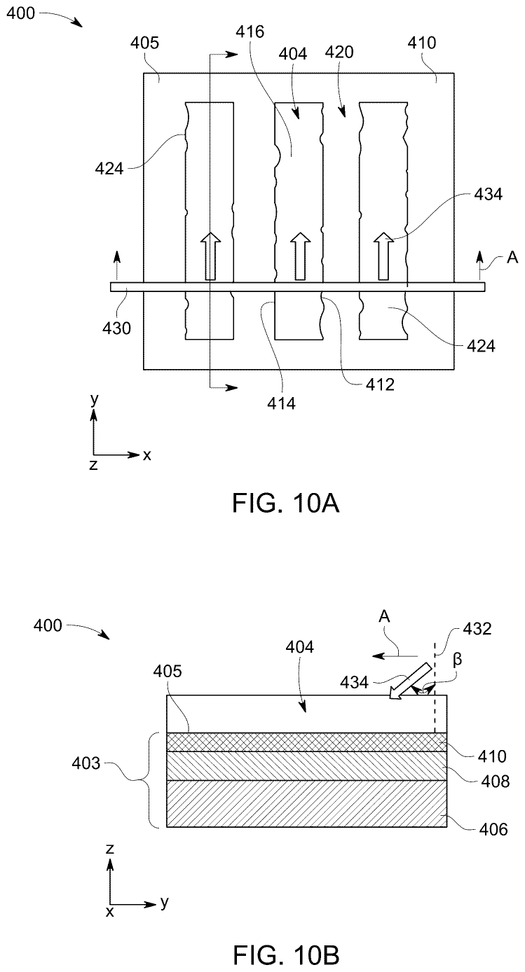

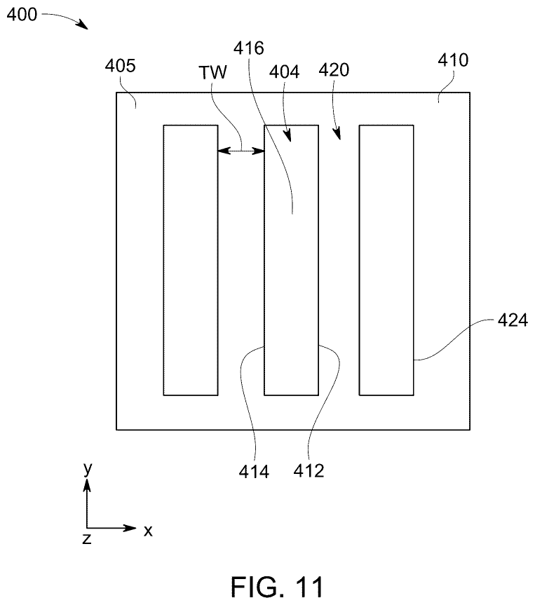

To remove these areas of surface roughness 424, as shown in FIGS. 10A-10B , a reactive plasma beam 430 may be delivered to the plurality of patterning lines 404 at a non-zero angle (β) relative to a perpendicular 432 (FIG. 10B) to a plane defined by the upper surface of the stack of layers 403. That is, angled ions 434 from the reactive plasma beam 430 may etch the areas of surface roughness 424 as the reactive plasma beam 430 is moving/scanning in the y-direction, as shown by arrow ‘A’. Although non-limiting, the angled ions 434 may include an inert gas species suitable for plasma dilution, such as helium (He), argon (Ar), nitrogen (N2), etc. Other etch chemistries may be used in alternative embodiments. For example, dissociation ions such as Ar+, H+, CH+, CF+, Cl+, Br+ may be used to reduce L/S roughness. Following the etch process, the areas of surface roughness 424 may be eliminated, or substantially reduced, as demonstrated in FIG. 11. The TW of each trench 420 does not increase as a result of the removal process, however. In other embodiments, TW may increase, if desired.

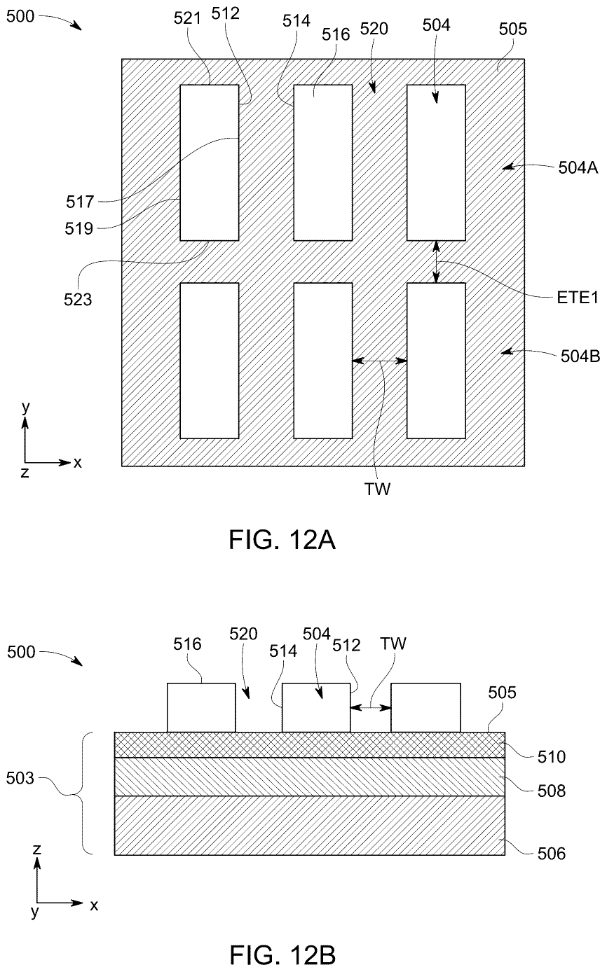

FIGS. 12A-12B depict a portion of another semiconductor device (hereinafter “device”) 500, according to one or more embodiments. The device 500 may include a stack of layers 503, and a plurality of patterning features or lines 504 formed atop an upper surface 505 of the stack of layers 503. Although non-limiting, the stack of layers 503 may include a base layer 506, a first underlayer 508 formed over the base layer 506, and a second underlayer 510 formed over the first underlayer 508.

Each of the plurality of patterning lines 504 may include a first sidewall 512 opposite a second sidewall 514, and an top surface 516 extending between the first and second sidewalls 512, 514. Furthermore, each of the patterning lines 504 may include a first side 517 opposite a second side 519, and a first end 521 opposite a second end 523. The plurality of patterning lines 504 may be defined by a plurality of openings or trenches 520 formed selective to the upper surface 505 of the stack of layers 503. The trenches 520 may have a trench width (TW) extending in the x-direction, between the first sidewall 512 and the second sidewall 514 of adjacent patterning lines 504.

In the embodiment shown, the plurality of patterning lines 504 may be arranged in rows, such as a first row 504A and a second row 504B, wherein the first and second rows 504A, 504B are separated from one another by an end-to-end distance (ETE1). More specifically, ETE1 represents a dimension between the first end 521 of the second row 504B of patterning lines 504 and the second end 523 of the first row 504A of the patterning lines 504.

Following formation of the plurality of patterning lines 504, one or more reactive plasma beams may be delivered to the plurality of patterning lines 504 at a non-zero angle (as described above with respect to FIGS. 2A-2B) . That is, angled plasma ions from the reactive plasma beam may either etch the patterning lines 504 and/or form additional material along the patterning lines 504 as the reactive plasma beam is moving/scanning in the y-direction. The angled plasma ions may also be delivered parallel and/or perpendicular to a plane defined by the first and second sidewalls 512, 514.

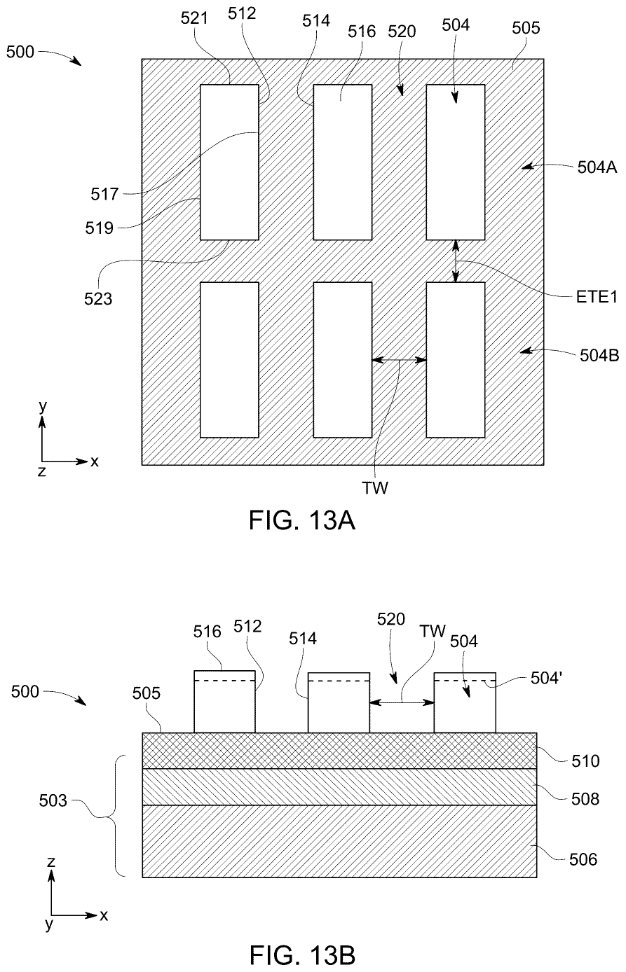

In the embodiment shown in FIGS. 13A-13B , a plasma deposition process is performed to add material to each of the patterning lines 504. More specifically, material is added to the top surface 516 of the patterning lines 504 without significantly adding material to the first and second sidewalls 512, 514. As a result, a width of each trench 520 essentially stays the same following the material formation process, as does the end-to-end distance between the first and second rows 504A, 504B. Only a height (e.g., in the z-direction) of the patterning lines 504 increases over the original patterning lines, which are demonstrated by dashed lines 504′.

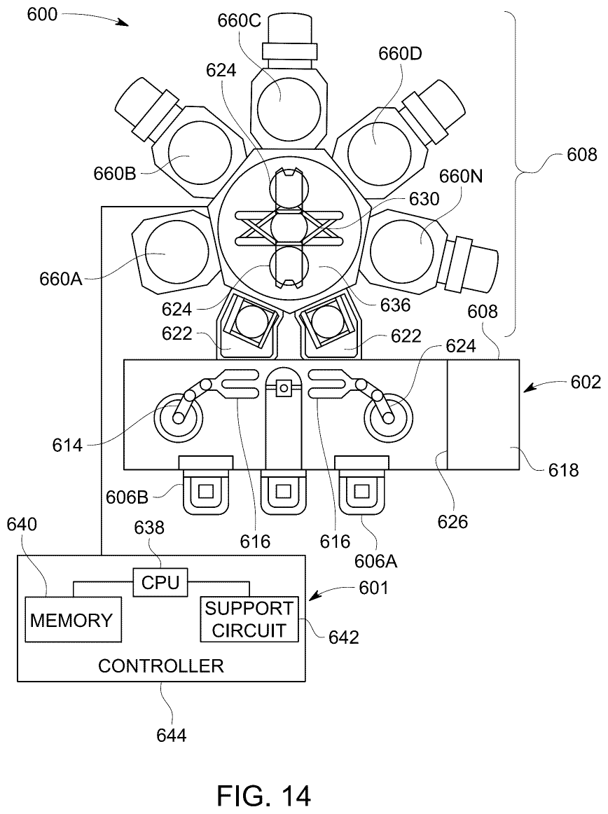

FIG. 14 is a schematic top plan view of an exemplary cluster processing system 600 that includes one or more of the processing chambers operable to form the devices 100, 200, 300, 400, and 500 described herein. In one embodiment, the cluster processing system 600 may be an integrated processing system commercially available from Applied Materials, Inc., located in Santa Clara, CA. It is contemplated that other processing systems (including those from other manufacturers) may be adapted to benefit from the disclosure.

The cluster processing system 600 may include a vacuum-tight processing platform 604, a factory interface 602, and a system controller 644. The platform 604 includes a plurality of processing chambers 660A-660N and at least one load-lock chamber 622 that is coupled to a vacuum substrate transfer chamber 636. Two load lock chambers 622 are shown in FIG. 14. The factory interface 602 is coupled to the transfer chamber 636 by the load lock chambers 622.

In one embodiment, the factory interface 602 comprises at least one docking station 608 and at least one factory interface robot 614 to facilitate transfer of substrates. The docking station 608 is configured to accept one or more front opening unified pod (FOUP). The factory interface robot 614 having a blade 616 disposed on one end of the robot 614 is configured to transfer the substrate from the factory interface 602 to the processing platform 604 for processing through the load lock chambers 622. Optionally, one or more metrology stations 618 may be connected to a terminal 626 of the factory interface 602 to facilitate measurement of the substrate from the FOUPS 606A-B.

Each of the load lock chambers 622 have a first port coupled to the factory interface 602 and a second port coupled to the transfer chamber 636. The load lock chambers 622 are coupled to a pressure control system (not shown) which pumps down and vents the load lock chambers 622 to facilitate passing the substrate between the vacuum environment of the transfer chamber 636 and the substantially ambient (e.g., atmospheric) environment of the factory interface 602.

In one embodiment of the cluster processing system 600, the cluster processing system 600 may include one or more processing chambers 660A-660N, which may include a deposition chamber (e.g., physical vapor deposition chamber, chemical vapor deposition, or other deposition chambers), annealing chamber (e.g., high pressure annealing chamber, RTP chamber, laser anneal chamber), etch chamber, cleaning chamber, curing chamber, lithographic exposure chamber, or other similar type of semiconductor processing chambers. More specifically, etch chamber 660A may include an etch tool operable to perform an angled etch using a reactive plasma beam delivered at a non-zero angle to reduce portions of the patterning lines, as described herein with respect to devices 100, 200, 300, 400, and 500. Meanwhile, deposition chamber 660B may include a deposition tool operable to perform an angled material/film deposition using a reactive plasma beam delivered at a non-zero angle to enhance/enlarge portions of the masking/patterning lines, as described herein with respect to devices 100, 200, 300, 400, and 500. In other embodiments, the etch and deposition processes can be performed in the same chamber, such as a Sculpta-type angled plasma beam chamber, e.g., by changing the chemistry being used in the chamber. The etch and deposition processes may occur sequentially, but they may also occur simultaneously, by running both the etch and the deposition chemistries at the same time.

The transfer chamber 636 has a vacuum robot 630 disposed therein. The vacuum robot 630 has one or more blades capable of transferring substrates 624 among the load lock chambers 622, the metrology system 610 and the processing chambers 660A-660N.

The system controller 644 is coupled to the cluster processing system 600. The system controller 644, which may include the computing device 601 or be included within the computing device 601, controls the operation of the cluster processing system 600 using a direct control of the processing chambers 660A-660N of the cluster processing system 600. Alternatively, the system controller 644 may control the computers (or controllers) associated with the processing chambers 660A-660N and the cluster processing system 600. In operation, the system controller 644 also enables data collection and feedback from the respective chambers to optimize performance of the cluster processing system 600.

The system controller 644, much like the computing device 601 described above, generally includes a central processing unit (CPU) 638, a memory 660, and support circuits 632. The CPU 638 may be one of any form of a general-purpose computer processor that can be used in an industrial setting. The support circuits 632 are conventionally coupled to the CPU 638 and may comprise cache, clock circuits, input/output subsystems, power supplies, and the like. The software routines transform the CPU 638 into a specific purpose computer (controller) 634. The software routines may also be stored and/or executed by a second controller (not shown) that is located remotely from the cluster processing system 600.

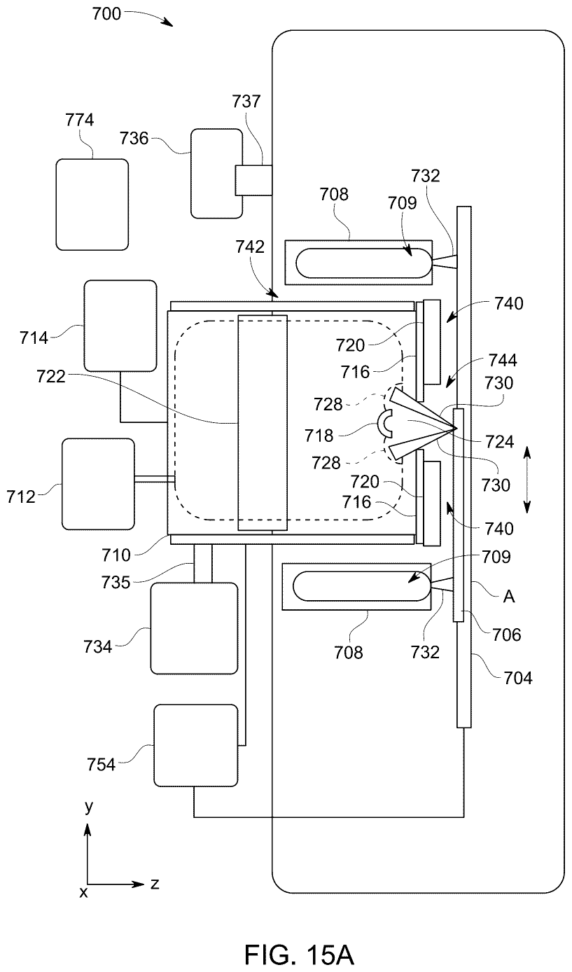

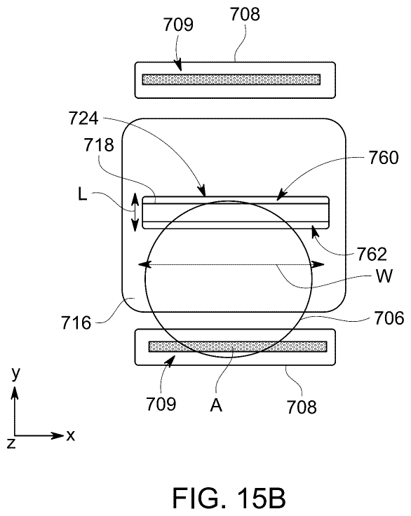

FIG. 15A is a schematic cross-sectional view of a processing apparatus 700 including an exemplary plasma processing chamber suitable for performing a patterning process. The plasma processing chamber may correspond to one of the processing chambers 660A-660N of the cluster processing system 600 described above. It is contemplated that other process chambers, including those from other manufactures, may be adapted to practice embodiments of the disclosure. It will be further contemplated that the components of the processing apparatus 700 are not necessarily to scale. The drawings are merely representations, not intended to portray specific parameters of the disclosure.

The apparatus 700 may include various components that operate together as an apparatus providing novel and improved etching of a substrate 706. As illustrated, the apparatus 700 may include a process chamber 702 and a substrate stage 704 disposed within the process chamber 702.

The apparatus 700 further includes at least one reactive gas source, shown as the reactive gas source 708. The reactive gas source 708 may have a reactive gas outlet 709 disposed within the process chamber 702. The reactive gas source 708 may be employed to deliver reactive gas 732 to a substrate 706 when the substrate 706 is adjacent the reactive gas source 708. In various embodiments, the reactive gas 732 may be capable of reacting with material of the substrate 706, wherein a first product layer comprising the reactive gas 732 and material from the substrate 706 is formed on an outer surface of the substrate. For example, in one particular non-limiting embodiment, the reactive gas 732 may comprise chlorine or a chlorine-containing material, while the substrate 706 is silicon. The reactive gas 732 may be delivered as a neutral species, may be delivered as a radical, may be delivered as an ion or may be delivered as a combination of neutrals, radicals and ions in some embodiments. A product layer may form as layer composed of a monolayer of chlorine species bonded to an underlayer of silicon species. The embodiments are not limited in this context.

The apparatus 700 further includes a plasma chamber 710. The plasma chamber 710 may include an extraction plate 716. As illustrated in FIG. 15A, the extraction plate 716 partially separates the plasma chamber 710 from the process chamber 702. The extraction plate 716 also includes an aperture 724 providing gaseous communication between the plasma chamber 710 and the process chamber 702, where the aperture 724 acts as an extraction aperture. In this manner, the plasma chamber 710 may be coupled to the process chamber 702. The aperture 724 may be an elongated aperture that extends along a first direction, such as parallel to the X-axis, as shown in FIG. 15B. For example, the aperture 724 may have a width ‘W’ ranging between 100 mm and 500 mm in some embodiments and a length ‘L’ ranging between 3 mm and 30 mm in some embodiments. The embodiments are not limited in this context. This elongated configuration of aperture 724 allows the extraction of an ion beam (“plasma beam”) as a ribbon beam, meaning an ion beam having a cross-section where the beam width is greater than a beam length.

As further shown in FIG. 15A, the apparatus 700 may include an inert gas source 712 coupled to the plasma chamber 710 to provide inert gas such as Ar, He, Ne, Kr, and so forth. The apparatus 700 may further include additional components such as a power generator 714, where the components together form a plasma source to generate a plasma 722.

The plasma 722 may be generated by coupling electric power from a power generator 714 to the rarefied gas provided by inert gas source 712 in the plasma chamber 710 through an adequate plasma exciter (not shown). As used herein, the generic term “plasma source” may include a power generator, plasma exciter, plasma chamber, and the plasma itself. The plasma source may be an inductively-coupled plasma (ICP) source, toroidal coupled plasma source (TCP), capacitively coupled plasma (CCP) source, helicon source, electron cyclotron resonance (ECR) source, indirectly heated cathode (IHC) source, glow discharge source, electron beam generated ion source, or other plasma sources known to those skilled in the art. Therefore, depending on the nature of the plasma source, the power generator 714 may be an rf generator, a dc power supply, or a microwave generator, while plasma exciter may include rf antenna, ferrite coupler, plates, heated/cold cathodes, helicon antenna, or microwave launchers. The apparatus 700 further may include a bias power supply 754 connected to the plasma chamber 710 or to a substrate stage 704, or to the plasma chamber 710 and substrate stage 704. Although not explicitly shown, the plasma chamber 710 may be electrically isolated from the process chamber 702. Extraction of a plasma beam 730 comprising positive ions through the aperture 724 may accomplished by either elevating the plasma chamber 710 at positive potential and grounding the substrate stage 704 directly or via grounding the process chamber 702, or by grounding the plasma chamber 710 and applying negative potential on the substrate stage 704. The bias power supply 754 may operate in either a dc mode or pulsed mode having a variable frequency and duty cycle, or an AC mode. The extraction plate 716 may be arranged generally according to known design to extract ions in the plasma beam 730 in a manner that allows control of the ion angular distribution, i.e., the angle of incidence of the plasma beam 730 with respect to a substrate 706 and the angular spread as detailed below.

In some embodiments, just one plasma beam 730 may be extracted through the aperture 724. In other embodiments, a pair of plasma beams may be extracted through the aperture 724. For example, as illustrated in FIG. 15A and FIG. 15B, a beam blocker 718 may be disposed within the plasma chamber 710 and adjacent the aperture 724, where the beam blocker 718 defines a first extraction aperture 760 and second extraction aperture 762. As shown in FIG. 15A, two plasma beams 730 may be extracted from the plasma chamber 710 and directed to the substrate 706.

As further shown in FIG. 15A, the apparatus 700 may include a pumping port 735 coupled to the plasma chamber 710 and a plasma chamber pump 734 connected to the pumping port 735. The plasma chamber pump 734 may be employed, for example, to reduce concentration of certain species within the plasma chamber 710, as discussed below. The apparatus 700 may further include a process chamber pump 736 coupled to the process chamber 702 via a pumping port 737 to evacuate the process chamber 702.

The apparatus 700 may further include a gas flow restrictor disposed between the reactive gas outlet and the extraction aperture, shown as the gas flow restrictor 720. As shown in FIG. 15A, for example, a gas flow restrictor 720 may be disposed on the outside of extraction plate 716 facing the substrate stage 704. The gas flow restrictor may define a differential pumping channel 740 between at least the plasma chamber 710 and substrate stage 704.

In operation, the substrate stage 704 may scan the substrate parallel to the Y-axis with respect to the extraction plate 716. In this manner, different portions of the substrate 706 may be exposed to the reactive gas 732 at different times. For example, the reactive gas outlet 709 may be elongated as shown in FIG. 15B and may have a width along the X-axis similar to the width W of the aperture 724, and a length along the Y-axis of 3 mm, for example. In various embodiments, the reactive gas outlet 709 may be composed of a multitude of small holes distributed over the X and Y dimensions to define an elongated shape as shown by the dashed lines, for uniform gas distribution along the X dimension. Moreover, the distance between the reactive gas source 708 and substrate 706 along the Z-axis may be 5 mm or less in some examples. The embodiments are not limited in this context. In this manner, the reactive gas 732 may be provided as a narrow, elongated stream that covers the substrate 706 in its entirety along the X-axis, while just covering the substrate 706 over several millimeters in the direction parallel to the Y-axis. Accordingly, the entirety of the substrate 706 may be exposed to the reactive gas 732 in a sequential fashion by scanning the substrate along the Y-axis. Likewise, different portions of the substrate 706 may be exposed to the plasma beam(s) 730 at different times.

Additionally, as illustrated in FIG. 15B, a given region, such as a region ‘A’ of the substrate 706, may be exposed to the reactive gas 732 and plasma beam 730 in a sequential fashion. In this manner, in an example of scanning the substrate 706 from bottom to top, a product layer made from the species of the reactive gas 732 and substrate 706 may initially be formed at the region ‘A’. The product layer may be an ALE layer as discussed above where the product layer is a monolayer formed by a self-limiting reaction. The product layer formed in region ‘A’ may be subsequently etched by the plasma beam 730, when the region ‘A’ is scanned upwardly under the plasma beam 730. In this manner, the substrate 706 may be etched in a monolayer-by-monolayer fashion by sequentially scanning the substrate under the reactive gas 732 and plasma beam 730.

In accordance with embodiments of the disclosure, the gas flow restrictor 720 may define a low conductance channel, shown as differential pumping channel 740, between at least the extraction plate 716 and substrate stage 704. As discussed below, the differential pumping channel 740 may establish a large pressure difference between one end of the differential pumping channel 740 and the other end. The reactive gas source 708 is separated from the plasma chamber 710 by a large conductance aperture in direct communication to a pumping source. The pumping source can be the process chamber pump 736 or any other pumping source made to communicate with aperture 742. In accordance with various embodiments, using appropriate design of aperture 742 and differential pumping channel 740 the partial pressure of the reactive gas in these two spatial regions may differ by 2 to 3 orders of magnitude. Using this differential pumping method, the apparatus 700 may, for example, maintain a partial pressure of the reactive gas 732 adjacent the reactive gas outlet 709 of 1E-3 Torr, while having a partial pressure of 1E-6 Torr at the region 744 adjacent the aperture 724, leading to the plasma chamber 710.

A result of this pressure differential is that species of reactive gas 732 may be prevented from backstreaming into the region 744 or into plasma chamber 710, and may be preferentially pumped through the pumping port 737. This may facilitate the ability to control the composition of plasma beam 730, such as reducing or eliminating reactive gas species from the plasma beam 730. In this manner, a more controllable etch process may be realized by maintaining the exposure of substrate 706 to reactive gas 732 separate from the exposure to the plasma beam 730. Additionally, or alternatively, the plasma chamber 710 may be evacuated by the plasma chamber pump 734, further reducing the concentration of species from reactive gas 732 in plasma chamber 710.

In accordance with various embodiments, the substrate stage 704 may be scanned sequentially under the reactive gas source 708 and plasma chamber 710 while the reactive gas source 708 and plasma chamber 710 are maintained in an ON state. In this manner, the apparatus 700 may provide a high throughput ALE process. In particular, a purge cycle may be avoided where the reactive gas 732 would otherwise be purged between exposure to reactive gas and exposure to an etching process (e.g., plasma beam 730) as in known ALE processes. Moreover, in some embodiments, the substrate stage 704 may scan a substrate 706 back and forth (up and down in FIG. 15A) in a continuous fashion for a predetermined number of scan cycles in order to etch a predetermined amount of material from substrate 706. Since the thickness of a given product layer may be readily calculated, the total thickness to be etched may readily be controlled according to the number of scan cycles to be performed.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method comprising:
forming a plurality of patterning lines over a stack of layers, wherein each of the plurality of patterning lines comprises a first sidewall and a second sidewall; and
delivering one or more reactive plasma beams to the plurality of patterning lines at a non-zero angle relative to a perpendicular to a plane defined by an upper surface of the stack of layers, wherein the one or more reactive plasma beams modulate a line critical dimension (CD) between a first pair of adjacent patterning lines of the plurality of patterning lines by performing at least one of the following: an angled etch to remove a material of the plurality of patterning lines from the first sidewall and the second sidewall, and an angled deposition to form an additional material along the first sidewall and the second sidewall.

2. The method of claim 1, wherein the one or more reactive plasma beams further reduce an end-to-end CD of a second pair of adjacent patterning lines of the plurality of patterning lines by performing the angled deposition to form the additional material along a first end and a second end of the second pair of adjacent patterning lines.

3. The method of claim 1, further comprising simultaneously performing the angled etch and the angled deposition.

4. The method of claim 1, wherein the angled etch further removes the material from a top surface of the first pair of adjacent patterning lines of the plurality of patterning lines, wherein the top surface extends between the first sidewall and the second sidewall.

5. The method of claim 1, wherein the angled deposition further forms the additional material along a top surface of the first pair of adjacent patterning lines of the plurality of patterning lines, wherein the top surface extends between the first sidewall and the second sidewall.

6. The method of claim 1, wherein the plurality of patterning lines are formed from an extreme ultraviolet resist or a deep ultraviolet resist.

7. The method of claim 1, wherein the plurality of patterning lines are formed from a metal-oxide resist or a chemically amplified resist.

8. The method of claim 1, wherein delivering the one or more reactive plasma beams comprises directing plasma ions to the plurality of patterning lines.

9. The method of claim 1, wherein performing the angled etch to remove the material of the plurality of patterning lines from the first sidewall and the second sidewall comprises removing an area of surface roughness along the first sidewall or the second sidewall.

10. A processing apparatus, comprising:
a chamber operable to contain a plasma within a chamber volume, the chamber defined by a plurality of sidewalls; and
a plate assembly proximate the chamber, wherein ions are extracted through a plurality of apertures of the plate assembly and delivered to a semiconductor device as a reactive plasma beam oriented at a non-zero angle relative to a perpendicular extending from an upper surface of a stack of layers of the semiconductor device, and wherein the reactive plasma beam modulates a line critical dimension (CD) between a first pair of adjacent patterning lines of a plurality of patterning lines by performing at least one of the following:
an angled etch to remove a material of the plurality of patterning lines from at least one of the following: a first sidewall, a second sidewall, and a top surface extending between the first and second sidewalls; and
an angled deposition to form an additional material along at least one of the following: the first sidewall, the second sidewall, and the top surface extending between the first and second sidewalls.

11. The processing apparatus of claim 10, wherein the reactive plasma beam further reduces an end-to-end CD of a second pair of adjacent patterning lines of the plurality of patterning lines by performing the angled deposition to form the additional material along a first end and a second end of the second pair of adjacent patterning lines.

12. The processing apparatus of claim 11, wherein the reactive plasma beam simultaneously forms the additional material along the first and second ends of the second pair of adjacent patterning lines and removes the material from the first and second sidewalls of the first pair of adjacent patterning lines.

13. The processing apparatus of claim 10, wherein the plurality of patterning lines are formed from a metal-oxide resist or a chemically amplified resist.

14. The processing apparatus of claim 10, wherein the ions extracted through the plurality of apertures of the plate assembly are plasma ions.

15. The processing apparatus of claim 10, wherein performing the angled etch to remove the material of the plurality of patterning lines from the first sidewall and the second sidewall comprises removing an area of surface roughness along the first sidewall or the second sidewall.

16. The processing apparatus of claim 10, wherein the additional material is formed along the top surface without being formed along the first sidewall or the second sidewall.

17. The processing apparatus of claim 10, further comprising simultaneously performing the angled etch and the angled deposition.

18. A method of modifying a plurality of resist lines formed over a stack of layers, the method comprising:
delivering one or more reactive plasma beams to the plurality of resist lines at a non-zero angle relative to a perpendicular to a plane defined by an upper surface of the stack of layers, wherein the one or more reactive plasma beams modulate a line critical dimension (CD) between a first pair of adjacent resist lines of the plurality of resist lines by performing at least one of the following:
an angled etch to remove a material of the plurality of resist lines from at least one of the following: a first sidewall, a second sidewall, and a top surface extending between the first and second sidewalls; and
an angled deposition to form an additional material along at least one of the following: the first sidewall, the second sidewall, and the top surface extending between the first and second sidewalls.

19. The method of claim 18, wherein the one or more reactive plasma beams further reduce an end-to-end CD of a second pair of adjacent resist lines of the plurality of resist lines by performing the angled deposition to form the additional material along a first end and a second end of the second pair of adjacent resist lines.

20. The method of claim 18, further comprising simultaneously performing the angled etch and the angled deposition.
